(19) United States
(12) Patent Application Publication
(10) Pub. No.: US 2004/0239211 A1
(43) Pub. Date: Dec. 2, 2004

(54) Surface wave device with weighted transducer

(76) Inventors: Steve Beaudin, Ottawa (CA); Chun-Yun Jian, Kanata (CA); Morris Repeta, Ottawa (CA)

Correspondence Address: SMART & BIGGAR/FETHERSTONHAUGH & CO., P.O. BOX 2999, STATION D, 900-55 METCALFE STREET, OTTAWA, ON, K1P5Y6, CA

(21) Appl. No.: 10/449,023

(22) Filed: Jun. 2, 2003

(51) Int. Cl. H03H 9/145

(52) U.S. Cl. 310/313 C

(57) ABSTRACT

A SAW device has a weighted IDT (inter-digital transducer) which is divided along its length into two or more sections with different relative weights of the weighting function, the IDT sections being coupled to a gain arrangement having different relative gains to compensate for the different relative weights of the IDT sections. The IDT can be amplitude weighted with an apodization pattern having lobes corresponding to the IDT sections, each section having a relative weight so that its maximum finger overlap corresponds to the aperture of the SAW device.

This invention relates to surface wave devices, and is particularly concerned with a surface wave device with a weighted transducer. The term “surface wave” is used herein to embrace various types of acoustic waves, including surface acoustic waves (SAWs), leaky SAWS, surface skimming bulk waves, and similar acoustic waves, and is abbreviated to SAW below.

### BACKGROUND OF THE INVENTION

It is well known to provide a SAW filter comprising two inter-digital transducers (IDTs) on a surface of a piezo-electric substrate for propagation of a SAW between the IDTs. In order to provide a desired filter characteristic, for example for a finite impulse response (FIR) filter, it is well known to apply weighting to one or both of the IDTs.

In a typical FIR SAW filter, one of the IDTs may be unweighted, i.e. may have uniform electrodes or fingers throughout its length, and the other IDT may be provided with a desired weighting pattern. The weighting may comprise apodization or amplitude weighting, in which the overlap lengths of adjacent fingers vary over the length of the IDT, or it may comprise withdrawal weighting, in which fingers are selectively omitted from the IDT in a manner that varies along the length of the IDT, or it may comprise a combination of these and/or other weighting methods.

For clarity, it is observed that the length of the IDT refers to its dimension in the direction of SAW propagation perpendicular to the fingers, the width of the IDT refers to its dimension perpendicular to its length, and the aperture of the IDT refers to that part of the width of the IDT within which SAWs are transduced and propagated. The length of the fingers refers to their dimension across the width of the IDT, and their width refers to their dimension perpendicular to their length, and hence in the length direction of the IDT. For simplicity as described herein the fingers are straight and perpendicular to the length of the IDT, but the IDT may also have fingers that are stepped, angled, slanted, curved, tapered or arranged in any other desired manner.

Each IDT may be bidirectional or may comprise a unidirectional IDT such as a SPUDT (single phase unidirectional transducer). Other techniques known in the art of SAW devices, such as the use of split or bifurcated fingers, dummy fingers, an inclined, preferably V-shaped, apodization axis, etc. can also be applied to the IDT. The IDT can be used as an input or an output transducer of the SAW device.

One important application of SAW FIR filters is as IF (intermediate frequency) bandpass filters, for example in wireless communications systems. Such applications present stringent requirements and consequently require high performance of the SAW filters. The cost of such SAW filters is dominated by the die size, or area of the piezoelectric substrate which is required for the SAW filter, which is predominantly determined by the area required for a weighted transducer of the SAW filter. With a smaller area or die size, not only can a wafer produce a proportionally greater number of SAW filters; the yield of good SAW filters from this greater number is also generally increased.

The area or die size is dependent upon the length and width of the weighted transducer. The length is determined by the required transition band, i.e. the filter characteristics, in accordance with the Fourier Transform and can not be changed unless IIR (infinite impulse response) filter techniques are used, or unless multi-strip coupling techniques are used, for example with two IDTs arranged adjacent one another both on the same side of a multi-strip coupler, with a consequent increase in the width of the SAW filter and no decrease in the required substrate area.

For an apodized or amplitude-weighted SAW filter, the width is determined by the minimum weight that is needed to reliably transduce and propagate a SAW at the filter frequency. For example, for an IF of 73.6 MHz the SAW wavelength on a quartz substrate is 42 μm and a typical die may be 20 mm long and 5 mm wide, the IDTs of a SAW filter on the die having an aperture of 4.2 mm and the weighted transducer having a length of about 400 wavelengths or 16.8 mm. This gives a weighting uncertainty of about 1/300 or −50 dB, and a variation of the first side lobe in the filter frequency response of about 2 dB.

Attempting to reduce the cost of such a SAW filter, by reducing its aperture and hence its width, increases the weighting uncertainty and side lobe variation, with adverse effects on manufacturability and yield. For example, halving the aperture to 2.1 mm increases the weighting uncertainty to 1/150 or −44 dB and the first side lobe variation to 7 dB, and further decreases in aperture produce corresponding increases in these parameters and other adverse effects such as variation in the filter transition band and significant in-band ripple.

It would be desirable to reduce the die size, and hence the cost, of a SAW filter in a manner that avoids or reduces such adverse effects. Alternatively, and in the case of a withdrawal weighted transducer, if would be desirable to facilitate an improved filter performance, with or without a decrease in the die size and hence the cost of the filter.

Accordingly, there is a need to provide such desirable results.

### SUMMARY OF THE INVENTION

According to one aspect, this invention provides a SAW (surface wave) device comprising an IDT (inter-digital transducer) weighted in accordance with a predetermined weighting function, wherein the IDT is divided along its length into a plurality of sections in which the weighting function has different relative weights.

For example, the IDT can comprise an apodized IDT and the weighting function can comprise an apodization pattern of the IDT. The apodization pattern can include a plurality of lobes, in which case preferably at least one of said plurality of sections into which the IDT is divided along its length corresponds to at least one of said plurality of lobes. In particular, the weighting function can correspond substantially to a sinc ((sin x)/x) function and the plurality of sections into which the IDT is divided along its length can correspond to different lobes of the sinc function. Desirably, at least two of said plurality of sections into which the IDT is divided along its length have different relative weights such that maximum overlaps of inter-digital fingers of the at least two sections correspond substantially to an aperture of the SAW device.

The invention also provides, in combination, a SAW device as recited above and a gain arrangement coupled to and providing different relative gains for said plurality of sections into which the IDT is divided along its length to compensate for the different relative weights of the weighting function in said plurality of sections.

Another aspect of the invention provides a SAW (surface wave) device comprising an IDT (inter-digital transducer) on a piezoelectric material, the IDT comprising inter-digital fingers extending from rails of the IDT and being weighted in accordance with a weighting function, wherein at least one of the rails of the IDT is divided along its length into a plurality of segments thereby to divide the IDT into a plurality of sections, and wherein the weighting function is applied to the inter-digital fingers with different relative weights in said plurality of sections.

For example, overlaps of the inter-digital fingers are weighted in accordance with an amplitude weighting function, such as at least approximately a sinc ((sin x)/x) function. The amplitude weighting function can include at least two lobes, at least one of the IDT sections corresponding to at least one of said lobes. Desirably, at least two of the IDT sections have different relative weights such that maximum overlaps of their inter-digital fingers correspond substantially, i.e. at least approximately, to an aperture of the SAW device.

The invention also provides, in combination, a SAW device as recited above and a gain arrangement coupled to and providing different relative gains for said plurality of segments of said at least one of the rails of the IDT. In particular, the different relative gains provided by the gain arrangement can compensate for the different relative weights of the weighting function in said plurality of sections of the IDT.

A further aspect of the invention provides a method of converting between an electrical signal and a propagated surface wave using a weighted inter-digital transducer (IDT) on a surface of a piezoelectric material, comprising the steps of: providing along a length of the IDT a plurality of sections of the IDT with different relative weights; and coupling the electrical signal to or from the plurality of sections with different relative gains.

The IDT can be weighted in accordance with an amplitude weighting function, and the different relative gains with which the electrical signal is coupled to or from the plurality of sections of the IDT can compensate for the different relative weights of the sections. In particular, the IDT can be weighted in accordance with an amplitude weighting function having a plurality of lobes along the length of the IDT, at least one of the plurality of sections of the IDT corresponding to at least one of said lobes.

### BRIEF DESCRIPTION OF THE DRAWINGS

The invention will be further understood from the following description with reference to the accompanying drawings, in which diagrammatically, not to scale, and by way of example:

FIG. 1 illustrates a known apodized transducer of a SAW device;

FIG. 2 illustrates an apodized transducer of a SAW device and a gain arrangement, in accordance with an embodiment of the invention;

FIG. 3 illustrates an apodized transducer of a SAW device and a gain arrangement, in accordance with another embodiment of the invention;

FIG. 4 is a graph illustrating frequency-gain characteristics for an implementation of the apodized transducer of FIG. 3; and

FIG. 5 illustrates a SAW device including a weighted transducer such as of FIG. 1.

### DETAILED DESCRIPTION

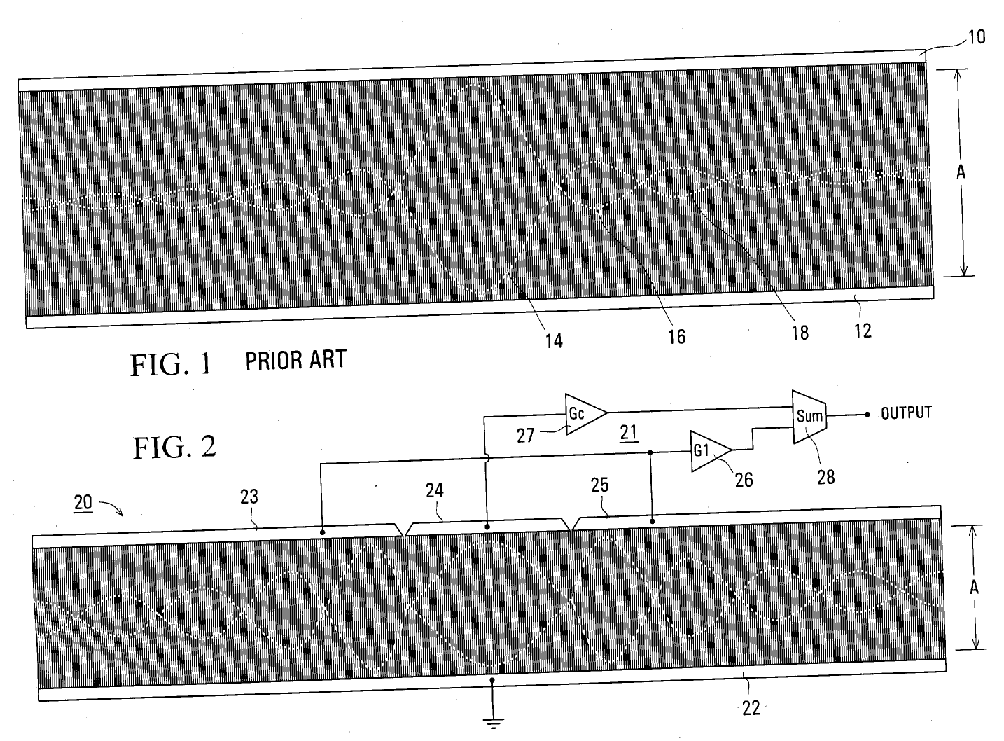

Referring to FIG. 1, a known apodized inter-digital transducer (IDT) of a SAW device is illustrated, the IDT being provided on a surface of a piezoelectric material which is represented by the plane of the drawing. The IDT comprises bus-bars or rails 10 and 12 which extend over the length of the IDT at each side of the IDT, with inter-digital electrodes or active fingers extending alternately from the rails 10 and 12 to overlap one another over a part of their lengths, and hence over part or all of the aperture A of the IDT.

The amount of the active finger overlap varies along the length of the IDT in accordance with a desired amplitude weighting or apodization pattern of the IDT. As illustrated in FIG. 1, the IDT is a bidirectional IDT with a symmetrical apodization pattern comprising a central lobe 14 and successive side lobes such as those referenced 16 and 18. For example, the IDT may have a length in the SAW propagation direction of about 400λ, where λ is the wavelength of the propagated SAW at a center frequency of the passband of the SAW filter, with a constant finger width and constant finger spacing each of λ/4, to provide substantially, i.e. at least approximately, a sinc ((sin x)/x) weighting function as illustrated in FIG. 1.

FIG. 1 also illustrates dummy electrodes or fingers extending from each of the rails 10 and 12, each dummy finger being between two adjacent active fingers extending from the same rail and not overlapping any finger extending from the other rail. Consequently, the fingers extending from each of the rails 10 and 12 have a constant periodicity of λ/2 over the entire length of the IDT.

A close inspection of FIG. 1 also shows that there is a polarity change (positions of the active and dummy fingers are reversed) between each pair of adjacent lobes of the weighting envelope, in accordance with changes in sign of the sinc function.

FIG. 5 illustrates a weighted IDT 50, such as that of FIG. 1, used in a known SAW filter. The weighted IDT 50 and an unweighted IDT 52 are arranged on a surface of a substrate 54 of piezoelectric material, such as quartz, for propagation of SAWs between the IDTs 50 and 52. As shown in FIG. 5, an electrical signal is supplied to the rail 10 of the IDT 50 via an input terminal, the rail 12 being grounded, and an electrical signal is derived from a rail 56 of the unweighted IDT 52 via an output terminal, the other rail 58 of the IDT 52 being grounded. The unweighted IDT 52 can have relatively few fingers, so that as can be appreciated from FIG. 5 the size of the substrate 54 is determined predominantly by the area of the weighted IDT 50.

It can be appreciated that the input and output functions of the IDTs 50 and 52 respectively in FIG. 5 can be reversed, that for either or both of the IDTs the electrical signal can be coupled to or from the rails in a differential or balanced manner instead of the unbalanced manner illustrated, that the IDT 52 may also be (e.g. amplitude and/or withdrawal) weighted if desired, and that the IDT 50 may have any desired form of weighting, for example withdrawal weighting instead of or as well as amplitude weighting. In the case of amplitude weighting or apodization, the apodization axis is preferably inclined or arranged in a straight or curved V-shape, instead of being parallel to the length of the IDT, for example as described in Suthers et al. U.S. Pat. No. 5,019,742 issued May 28, 1991 and entitled “SAW Device With Apodized IDT”, in order to reduce undesired coupling as taught in the patent. It will be appreciated by persons of ordinary skill in the art that similar variations can be applied to embodiments of the invention as described below.

It will be appreciated from FIG. 5 that the size of the substrate 50 can only be significantly decreased by decreasing the size of the weighted IDT 50. Further, it will be appreciated from FIG. 1 that this would involve reducing the length of the IDT, which is inconsistent with achieving a desired FIR filter performance, or its aperture A, which would introduce the disadvantages discussed in the Background of the Invention above.

FIG. 2 illustrates an apodized IDT 20 of a SAW device and a gain arrangement 21 in accordance with an embodiment of the invention. In the example of FIG. 2 the IDT 20 supplies unbalanced signals to the gain arrangement 21, and accordingly has a bus-bar or rail 22 which is grounded as illustrated, and the gain arrangement 21 provides an electrical signal to an output terminal. It will be apparent to persons of ordinary skill in the art how to modify this for balanced signals (e.g. dividing the rail 22 into sections as for the other rail as described below) and/or an input signal to the IDT (e.g. reverse the amplifiers described below to drive the IDT, and replace the signal combiner by a signal splitter or simple connection).

The IDT 20 in FIG. 2 is divided along its length into a plurality of, in this case three, sections by splitting its other bus-bar or rail into three parts referenced 23, 24, and 25 in FIG. 2. Each of the IDT sections has a respective signal output from the respective rail 23, 24, and 25, and has a respective relative weight as described further below. In this example the rail 24 extends along that part of the length of the IDT 20 which corresponds to the central lobe of the sinc weighting function for which the IDT section has a first relative weight, and the rails 23 and 25 extend along the parts of the length of the IDT 20 which correspond to the side lobes to the left and to the right, respectively, of the central lobe of the sinc weighting function, both of these IDT sections having the same, second, relative weight which is different from the first relative weight. The three sections of the IDT 20 delimited by the rails 23, 24, and 25 in this example are accordingly referred to as the left, center, and right sections respectively.

Between the rail 22 and the rails 23 to 25 the IDT 20 includes overlapping active fingers and dummy fingers extending from the rails and providing a sinc weighting function as in the prior art of FIG. 1, but the sinc weighting function is modified in accordance with the relative weighting of the three sections.

More particularly, in the central section the active fingers are overlapped in accordance with the central lobe of the sinc weighting function in the same manner as in FIG. 1 but with a relatively reduced aperture A of the IDT 20. Thus it will be seen that the IDT 20 of FIG. 2 is appreciably less wide than the IDT of FIG. 1.

In the left section of the IDT 20, the active fingers are overlapped in accordance with the left side lobes of the sinc weighting function, but scaled so that the greatest overlap in the largest side lobe, i.e. the first side lobe to the left of the central lobe, is equal to the aperture A of the IDT 20. Similarly, in the right section of the IDT 20, the active fingers are overlapped in accordance with the right side lobes of the sinc weighting function, but scaled so that the greatest overlap in the largest side lobe, i.e. the first side lobe to the right of the central lobe, is equal to the aperture A of the IDT 20. Thus it be seen that the side lobes of the weighting function for the IDT 20 of FIG. 2 are larger than those of the IDT of FIG. 1, despite the reduction of the aperture A.

Because in this example the IDT 20 is symmetrical about its central section, the scaling of the left and right sections is the same. In this case as shown in FIG. 2 the signal outputs from the respective rails 23 and 25 can be, and are, connected together and to an input of an amplifier 26 of the gain arrangement 21, providing a relative gain G1. The signal output from the rail 24 of the central section of the IDT 20 is connected to the input of an amplifier 27 of the gain arrangement 21, having a relative gain Gc. The relative gains Gc and G1 are selected to compensate precisely for the relative scaling of the sections of the IDT 20; thus the relative gain Gc is greater than the relative gain G1, because the amplitude weighting of the central section of the IDT has been reduced whereas the amplitude weighting of the left and right sections has been increased. A signal combiner or summing function 28 of the gain arrangement 21 sums the outputs of the amplifiers 26 and 27 to produce an output signal from the IDT and gain arrangement.

For example, for the sinc weighting function the magnitude ratio of the center lobe to the first side lobe is 4.72, providing a signal difference of 13.48 dB. Accordingly, it can be appreciated that the gain Gc of the amplifier 27 can be 13.48 dB greater than the gain G1 of the amplifier 26. Attenuator pads (not shown) can be provided at the outputs of the amplifiers 26 and 27 for precise trimming of their relative gains. It can be appreciated that the gain arrangement 21 including the amplifiers 26 and 27 can be provided in place of or in addition to an amplifier conventionally provided for amplifying the output signal of a SAW device.

Correspondingly, it can be appreciated that the aperture A of the IDT 20 in FIG. 2 can be reduced by the factor of 4.72 from the aperture of the IDT of FIG. 1, while providing substantially the same filter response. Thus the area of the IDT 20, and hence the die size required for a SAW filter using this IDT, can be substantially reduced, for example by a factor of five from a die size of 20 mm by 5 mm to a die size of 20 mm by 1 mm. Thus in manufacture a wafer can produce five times as many SAW filters as in the prior art. Furthermore, the manufacturing yield will generally also be increased, because spot defects are likely to affect only the same actual number of SAW filters in each case. Consequently, the cost per SAW filter can be reduced by a considerable factor.

Alternatively, the aperture A of the IDT 20 in FIG. 2 can be reduced from the aperture of the IDT of FIG. 1 by a smaller factor, enabling the SAW filter to be provided with a better noise figure due to the relatively increased size of the side lobes, and/or improved linearity. Thus the apodized IDT and gain arrangement of FIG. 2 enables an improved selection to be made among the SAW filter size and the noise figure and linearity of a receiver or other circuit including the SAW filter.

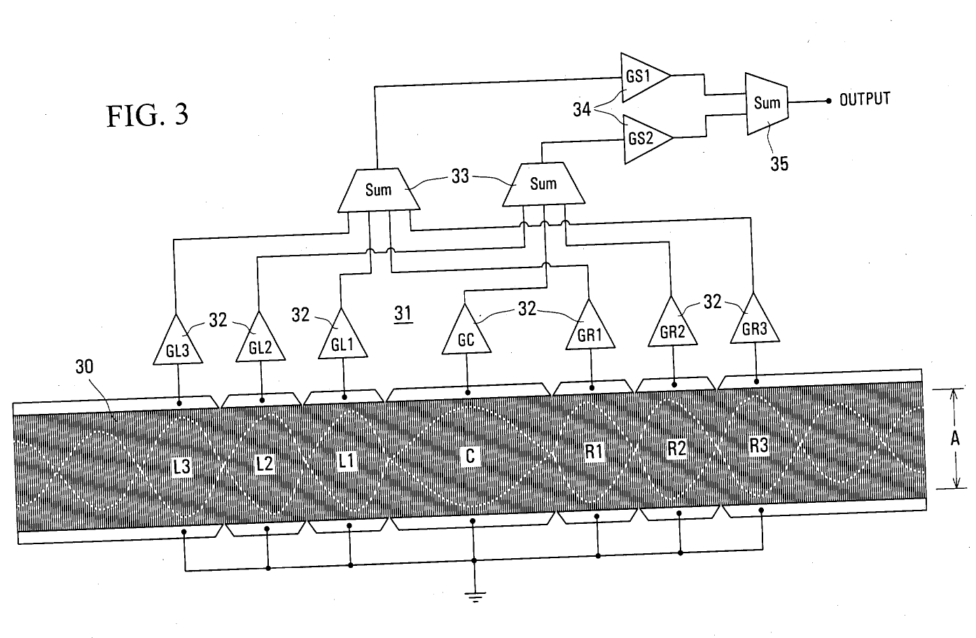

FIG. 3 illustrates an apodized transducer 30 of a SAW device and a gain arrangement 31, in accordance with another embodiment of the invention, again having substantially a sinc weighting function. The IDT 30 of FIG. 3 is divided along its length, by dividing in this case both rails of the IDT, into seven sections, namely a central section C corresponding to the central lobe of the sinc function, and first second, and third sections L1 to L3 to the left and R1 to R3 on the right of the central section, corresponding respectively to the first side lobe, second side lobe, and third and outer side lobes of the sinc weighting function. Each of these sections of the IDT 30 has a respective relative weight, selected so that the maximum finger overlap in each section is substantially equal to the aperture A of the IDT 30. The IDT 30 of FIG. 3 is otherwise similar to the IDT 20 of FIG. 2.

The gain arrangement 31 of FIG. 3 includes seven amplifiers 32, two summing units 33, two further amplifiers 34, and a further summing unit 35. Each of the seven amplifiers 32 has an input connected to a respective one of the seven sections of one rail of the IDT 30, the seven sections of the other rail of the IDT 30 all being grounded as illustrated. The amplifiers 32 provide respective gains GL3 to GL1, GC, and GR1 to GR3 for signals from the seven sections L3 to L1, C, and R1 to R3 respectively of the IDT 30.

Outputs of the amplifiers 32 for the central section C and the second side lobe sections L2 and R2, having a first polarity of the IDT fingers, are supplied to inputs of one of the summing units 33, whose output is supplied via one of the amplifiers 34 having a gain GS2 and supplied to one input of the further summing unit 35. Outputs of the other amplifiers 32 for the first and third (and outer) side lobe sections L1, L3 and R1, R3 having a (predominantly) opposite polarity of the IDT fingers are supplied to inputs of the other of the summing units 33, whose output is supplied via the other of the amplifiers 34 having a gain GS1 and supplied to the other input of the further summing unit 35. The output of the further summing unit 35 constitutes an output of the IDT and gain arrangement of FIG. 3.

In a similar manner to that described above with reference to FIG. 2, the relative gains of the amplifiers 32 and 34 are selected to compensate for the relative scaling of the respective sections of the IDT 30. For example, for the sinc weighting function the scaling illustrated in FIG. 3 increases the signals from the first, second, and third and outer side lobes by respectively 13.48, 18.47, and 22.03 dB. It can be appreciated that the gains of the amplifiers 32 and 34 can be selected to compensate for this scaling in various ways. For example, the gains GS1 and GS2 of the amplifiers 34 may be equal, and the gain GC may be 22.03 dB greater than the gains GL3 and GR3, 18.47 dB greater than the gains GL2 and GR2, and 13.48 dB greater than the gains GL1 and GR1. Attenuator pads (not shown) can be provided at the outputs of the amplifiers 32 and 34 for precise trimming of their relative gains.

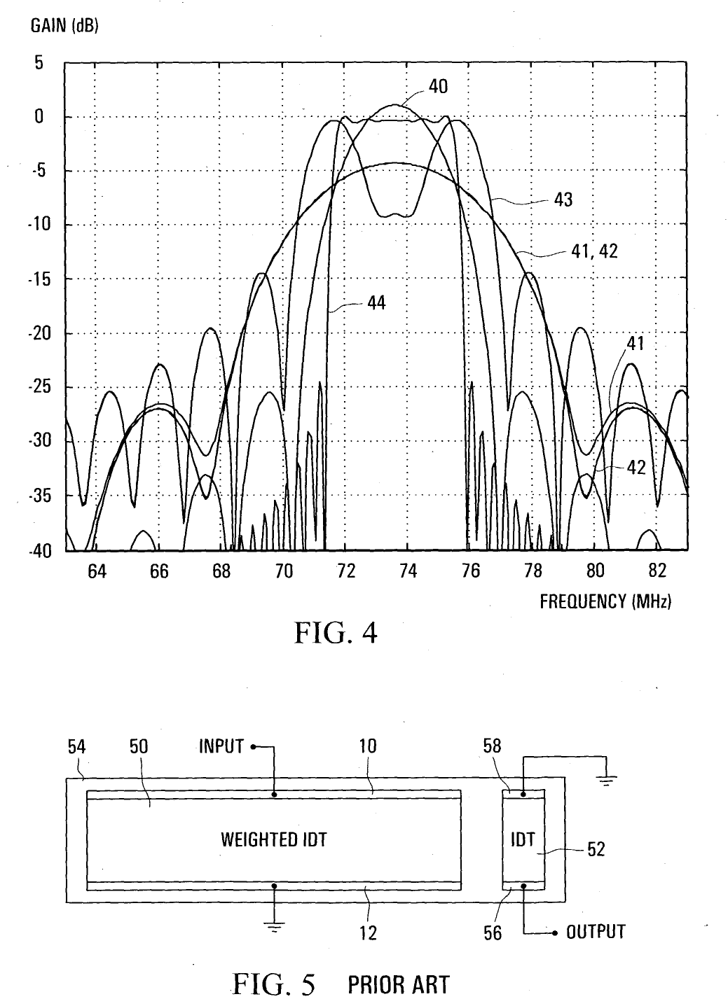

FIG. 4 is a graph illustrating frequency-gain characteristics for one implementation of the IDT 30 and gain arrangement 31 of FIG. 3. In FIG. 4, a line 40 represents the frequency response for the central section C of the IDT 30 for a center frequency of 73.6 MHz, and lines 41, 42, and 43 represent frequency responses for respectively the first, second, and third and outer scaled side lobes as described above, the responses being the same for corresponding side lobes on the left and right sides of the central lobe. A line 44 represents a desirable overall response of the IDT and gain arrangement.

Although as described above the sections into which the IDT is divided correspond to lobes of a sinc weighting function, and this is preferred because of the substantially zero response at the resulting divisions, this need not be the case. The IDT may have any desired weighting function, and can be divided into two or more sections at one or more other points along its length, the sections having different relative weights as described above. The transitions between the sections may also or alternatively be progressive or gradual. It will also be appreciated that the IDT need not be symmetrical as described above. Further, the IDT need not be bidirectional as described above, but could instead, for example, be a unidirectional IDT such as a SPUDT.

In addition, although as described above each section of the IDT is scaled or weighted so that the maximum finger overlap in each section corresponds substantially to the aperture A of the IDT, this need not be the case and any other desired scaling or weighting of the different sections of the IDT may be provided. Further, although as described above the gain arrangements comprise amplifiers, it can be appreciated that each gain arrangement can comprise any desired combination of amplifying and/or attenuating elements to provide the desired relative gains (which may be greater than, equal to, or less than one), and that the summing units may include weighting to provide some or all of the desired relative gains.

For example, in one implementation of the invention the IDT can have a form similar to that shown in FIG. 2, the path from the rail 24 to the summing function 28 can have a relative gain of 1 and so the gain element or amplifier 27 can be omitted, the interconnected paths from the rails 23 and 25 to the summing function 28 can have a relative gain less than 1 so that the gain element or amplifier 26 can be constituted by an attenuator, and any desired signal amplification can be provided in and/or subsequent to the summing function 28. A converse arrangement, in which an IDT signal driver drives the rail 24 directly (relative gain=1) and drives the rails 23 and 25 via an attenuator (relative gain less than one), can also be provided.

Also, it will be appreciated that matching networks, not shown in the drawings, can be provided between the transducer sections and the gain arrangement, or may be incorporated into the gain arrangement, to tune out static capacitance of the transducer sections and for impedance matching in known manner.

As indicated above, the apodization axis of the amplitude weighted IDT is preferably inclined in a V-shape as taught by Suthers et al. U.S. Pat. No. 5,019,742 referred to above. This reduces the lengths of fingers extending from the driven rails of the IDT at the divisions between the sections of the IDT, for example at the divisions between the rail 24 and the rails 23 and 25 in the IDT of FIG. 2, and hence reduces adverse effects of coupling between such fingers which may be at different potentials.

Furthermore, although as described above the IDT is weighted by apodization or amplitude weighting, it may alternatively or additionally be weighted in another manner, for example by withdrawal weighting in known manner. Thus for example a withdrawal weighted IDT may be divided into a plurality of sections with different relative scaling or weights for the different sections as described above, and compensation for these by different amplifier and/or attenuator gains for example as described above, to provide improved characteristics such as noise figure or linearity, with or without a reduced aperture of the IDT. As the length of a withdrawal weighted IDT may typically correspond to a single lobe of a weighting function, in this case the divisions will typically not be at substantially zero points of the weighting function.

In addition, it will be appreciated as indicated above that the IDT and gain arrangement can be provided on the input and/or the output side of a SAW filter, and that the arrangement can comprise unbalanced connections as described above or it can comprise balanced or differential connections as known in the art of SAW filters.

Also, as noted above the SAW filter can alternatively have a folded arrangement with the two IDTs arranged adjacent one another and coupled in known manner via a multi-strip coupler on the piezoelectric substrate, thereby decreasing the length and increasing the width of the substrate. In this case either or both of the IDTs may be weighted, and the techniques described above can be applied to each weighted IDT.

Thus although particular embodiments of the invention are illustrated by way of example and are described in detail above, it can be appreciated that these and numerous other modifications, variations, and adaptations may be made within the scope of the invention as defined in the claims.

What is claimed is:

1. A SAW (surface wave) device comprising an IDT (inter-digital transducer) weighted in accordance with a predetermined weighting function, wherein the IDT is divided along its length into a plurality of sections in which the weighting function has different relative weights.

2. A SAW device as claimed in claim 1 wherein the IDT comprises an apodized IDT and the weighting function comprises an apodization pattern of the IDT.

3. A SAW device as claimed in claim 2 wherein the apodization pattern includes a plurality of lobes, and at least one of said plurality of sections into which the IDT is divided along its length corresponds to at least one of said plurality of lobes.

4. A SAW device as claimed in claim 3 wherein the different relative weights of at least two of said plurality of sections into which the IDT is divided along its length are such that the at least two sections have inter-digital fingers which overlap over substantially an aperture of the SAW device.

5. A SAW device as claimed in claim 2 wherein at least two of said plurality of sections into which the IDT is divided along its length have different relative weights such that maximum overlaps of inter-digital fingers of the at least two sections correspond substantially to an aperture of the SAW device.

6. A SAW device as claimed in claim 2 wherein the weighting function corresponds substantially to a sinc ((sin x)/x) function and the plurality of sections into which the IDT is divided along its length correspond to different lobes of the sinc function.

7. A SAW device as claimed in claim 6 wherein at least two of said plurality of sections into which the IDT is divided along its length have different relative weights such that maximum overlaps of inter-digital fingers of the at least two sections correspond substantially to an aperture of the SAW device.

8. In combination, a SAW device as claimed in claim 1 and a gain arrangement coupled to and providing different relative gains for said plurality of sections into which the IDT is divided along its length to compensate for the different relative weights of the weighting function in said plurality of sections.

9. In combination, a SAW device as claimed in claim 2 and a gain arrangement coupled to and providing different relative gains for said plurality of sections into which the IDT is divided along its length to compensate for the different relative weights of the weighting function in said plurality of sections.

10. In combination, a SAW device as claimed in claim 3 and a gain arrangement coupled to and providing different relative gains for said plurality of sections into which the IDT is divided along its length to compensate for the different relative weights of the weighting function in said plurality of sections.

11. A SAW (surface wave) device comprising an IDT (inter-digital transducer) on a piezoelectric material, the IDT comprising inter-digital fingers extending from rails of the IDT and being weighted in accordance with a weighting function, wherein at least one of the rails of the IDT is divided along its length into a plurality of segments thereby to divide the IDT into a plurality of sections, and wherein the weighting function is applied to the inter-digital fingers with different relative weights in said plurality of sections.

12. A SAW device as claimed in claim 11 wherein overlaps of the inter-digital fingers are weighted in accordance with an amplitude weighting function.

13. A SAW device as claimed in claim 12 wherein the amplitude weighting function includes at least two lobes, and at least one of the IDT sections corresponds to at least one of said lobes.

14. A SAW device as claimed in claim 13 wherein at least two of the IDT sections have different relative weights such that maximum overlaps of their inter-digital fingers correspond substantially to an aperture of the SAW device.

15. A SAW device as claimed in claim 14 wherein the weighting function corresponds substantially to a sinc ((sin x)/x) function.

16. In combination, a SAW device as claimed in claim 11 and a gain arrangement coupled to and providing different relative gains for said plurality of segments of said at least one of the rails of the IDT.

17. The combination as claimed in claim 16 wherein the different relative gains provided by the gain arrangement compensate for the different relative weights of the weighting function in said plurality of sections of the IDT.

18. In combination, a SAW device as claimed in claim 12 and a gain arrangement coupled to and providing different relative gains for said plurality of segments of said at least one of the rails of the IDT to compensate for the different relative weights of the weighting function in said plurality of sections of the IDT.

19. A method of converting between an electrical signal and a propagated surface wave using a weighted inter-digital transducer (IDT) on a surface of a piezoelectric material, comprising the steps of:
providing along a length of the IDT a plurality of sections of the IDT with different relative weights; and
coupling the electrical signal to or from the plurality of sections with different relative gains.

20. A method as claimed in claim 19 wherein the IDT is weighted in accordance with an amplitude weighting function.

21. A method as claimed in claim 19 wherein the different relative gains with which the electrical signal is coupled to or from the plurality of sections of the IDT compensate for the different relative weights of the sections.

22. A method as claimed in claim 19 wherein the IDT is weighted in accordance with an amplitude weighting function having a plurality of lobes along the length of the IDT, and at least one of the plurality of sections of the IDT corresponds to at least one of said lobes.
